(19) United States
(12) Patent Application Publication
(10) Pub. No.: US 2024/0356191 A1
(43) Pub. Date: Oct. 24, 2024

(54) TRANSMISSION LINE SUBSTRATE

(71) Applicant: Nippon Telegraph and Telephone Corporation, Tokyo (JP)

(72) Inventors: Miwa Muto, Tokyo (JP); Hideaki Matsuzaki, Tokyo (JP)

(21) Appl. No.: 18/683,658

(22) PCT Filed: Sep. 28, 2021
(86) PCT No.: PCT/JP2021/035567

§ 371 Date: Feb. 14, 2024

(51) Int. Cl. H01P 3/08

(52) U.S. Cl. CPC H01P 3/088; H01P 3/082

(57) ABSTRACT

The transmission line substrate includes a first transmission line of a first line length on a substrate made of a dielectric material and connects a first integrated circuit and a second integrated circuit, a first dielectric layer having a first dielectric constant covering the first integrated circuit, the second integrated circuit and the first transmission line, a second dielectric layer having a second dielectric constant formed on the first dielectric layer, a first columnar via connected to the first integrated circuit, a second columnar via connected to the second integrated circuit, and a second transmission line having a second line length in the second dielectric layer and connected to the first via and the second via. A first dielectric constant and a second dielectric constant are set so that the signal transmission times in each of the first transmission line and the second transmission line are equal.

### CROSS-REFERENCE TO RELATED APPLICATIONS

This application is a national phase entry of PCT Application No. PCT/JP2021/035567, filed on Sep. 28, 2021, which application is hereby incorporated herein by reference.

### TECHNICAL FIELD

The present invention relates to a transmission line substrate.

### BACKGROUND

In recent years, with increases in the frequency of this kind of module, a configuration of a transmission line has been extremely important in a high-frequency transmission line substrate to transmit a signal at a high speed without causing an operation error. For example, in a case where a plurality of integrated circuits are integrated on the transmission line substrate, all the wirings for transmitting high-frequency signals are desired to be connected by wirings having the same length. For example, as shown in FIG. 3, input/output portions of a first integrated circuit 302 and a second integrated circuit 303 which are integrated on a substrate 301 and connected to each other are disposed to face each other, and if connection intervals of each transmission line are the same, the transmission lines can be formed with the same line length.

However, in general, since the input/output portions are formed on all the outer peripheral portions of the integrated circuit, each of the transmission lines is actually formed with a different wiring length. When the transmission lines are formed with different wiring lengths, a difference occurs in transmission times of signals transmitted to the transmission lines. Thus, the transmission line substrate has problems such as malfunction of processing due to timing deviation and generation of noise.

In order to propagate a high-speed signal on the high-frequency transmission line substrate, a microstrip line, a coplanar line, a grounded coplanar line or the like is used as a typical transmission line structure. For example, the microstrip line forms a transmission line by forming a ground surface of a planar conductor layer on one surface of a dielectric substrate and forming a strip-like line on the other surface. The characteristic impedance of these lines is determined by the width and thickness of the signal line, the dielectric constant and thickness of the dielectric substrate, and the geometric dimension of the gap between the signal line and the ground pattern.

In addition, reduction in power consumption as well as high frequency is also an important factor, and miniaturization and high density are required for reduction in power consumption. For example, in a configuration in which corresponding wirings are connected to each other with the same length, redundant wirings are formed. The longer the wiring length is, the greater the loss is, and the formation of a number of folded parts also influences the signal quality such as causing loss at high frequencies.

### CITATION LIST

### Patent Literature

PTL 1 Japanese Patent Application Publication No. 2003-198215

### SUMMARY

### Technical Problem

There have been various studies on transmission line substrates to solve problems caused by transmission lines and balanced lines having different wiring lengths. For example, in the transmission line substrate shown in FIG. 4, a first integrated circuit 402 and a second integrated circuit 403 are mounted on a dielectric substrate 401, and a plurality of patterns of transmission lines for connecting input/output portions of the opposite integrated circuits are formed on the dielectric substrate 401. In the transmission line substrate, the transmission lines are formed to have substantially the same line length.

In the transmission line substrate, input/output portions are provided on sides 402a, 402b and 402c of the first integrated circuit 402, and input/output portions are provided on sides 403a, 403b and 403c of the second integrated circuit 403. A distance between the input/output portion of the side 402a and the input/output portion of the side 403a is a maximum length. Next, a distance between the input/output portion of the side 402b and the input/output portion of the side 403b becomes an intermediate length. Next, a distance between the input/output portion of the side 402c and the input/output portion of the side 403c becomes a minimum length.

In the transmission line substrate, a second transmission line 412a is pattern-formed on the dielectric substrate 401 so that the respective line lengths are matched with each other, on the basis of a first transmission line 411a that connects an input/output portion provided on a side 402a of the first integrated circuit 402 and an input/output portion provided on a side 403a of the second integrated circuit 403. The line length of the second transmission line 412a is made almost the same as the line length of the first transmission line 411a by forming a refraction part in a part of the second transmission line 412a. Further, the fourth transmission line 412b is formed into a so-called meander pattern in which many folded parts are formed, so that the line length is made almost the same as that of the third transmission line 411b.

However, since the transmission line substrate having the above-described configuration is designed to have an equal-length wiring by intentionally forming a bent part or a folded part on a transmission line having a short linear distance, the line length becomes long, and a so-called redundant wiring structure is obtained. In the transmission line substrate of this kind, reduction in power consumption is pursued, and the above-mentioned redundant wiring structure has a large loss and is not practical.

In addition, the transmission line substrate of this kind has not only a problem of an increase in an impedance component due to an increase in the line length of the transmission line and deterioration in the transmission efficiency of the high frequency signal, but also a problem of deterioration of the electromagnetic matching characteristic and the electromagnetic interference noise characteristic due to the likelihood of radiation or reception of electromagnetic noise.

Further, when the transmission lines are formed to have different lengths, the phase shift amounts of the high-frequency signals transmitted to the transmission lines are different from each other. Therefore, there is a problem that the loss of the high-frequency signal after conversion becomes large. As circuit components and circuit elements are made multifunctional and highly functional, the number and density of input/output terminals also increase. Therefore, it is extremely difficult to achieve the above-described countermeasure, the redundant wiring becomes complicated and longer, and problems such as an increase in size and deterioration in characteristics further increase.

Embodiments of the present invention have been made to solve the above problems, and an object of embodiments of the present invention is to enable high-frequency signals to be transmitted, without making the wiring structure redundant, and without increasing the loss between transmission lines of different line lengths.

### Solution to Problem

A transmission line substrate according to embodiments of the present invention includes a first integrated circuit and a second integrated circuit disposed on a substrate made of a dielectric; a first transmission line of a first line length which is formed on the substrate, and connects the first integrated circuit and the second integrated circuit; a first dielectric layer which is formed to cover the first integrated circuit, the second integrated circuit, and the first transmission line, and is made of a dielectric having a first dielectric constant; a second dielectric layer which is formed on the first dielectric layer, and is made of a dielectric having a second dielectric constant; a columnar first via which is connected to the first integrated circuit, and penetrates through the first dielectric layer to a middle of the second dielectric layer; a columnar second via which is connected to the second integrated circuit, and penetrates through the first dielectric layer to the middle of the second dielectric layer; a second transmission line of a second line length which is formed in the second dielectric layer, and is connected to the first via and the second via to connect the first integrated circuit and the second integrated circuit; and a ground layer formed on a back face of the substrate, in which, when the first line length is longer than the second line length, the second dielectric constant is lower than the first dielectric constant, and when the second line length is longer than the first line length, the first dielectric constant is lower than the second dielectric constant.

### Advantageous Effects of Embodiments of the Invention

As described above, according to embodiments of the present invention, when the first line length is longer than the second line length, the second dielectric constant is lower than the first dielectric constant, and when the second line length is longer than the first line length, the first dielectric constant is lower than the second dielectric constant. Accordingly, a high frequency signal can be transmitted, without making a wiring structure redundant and without increasing loss between transmission lines having different line lengths.

### BRIEF DESCRIPTION OF THE DRAWINGS

FIG. 1A is a cross sectional view showing a configuration of a transmission line substrate according to a first embodiment of the present invention.

FIG. 1B is a plan view showing a partial configuration of the transmission line substrate according to the first embodiment of the present invention.

FIG. 1C is a cross-sectional view showing the configuration of the transmission line substrate according to the first embodiment of the present invention.

FIG. 2A is a cross-sectional view showing a configuration of a transmission line substrate according to a second embodiment of the present invention.

FIG. 2B is a cross-sectional view showing the configuration of the transmission line substrate according to the second embodiment of the present invention.

FIG. 3 is a plan view showing a configuration of the transmission line substrate.

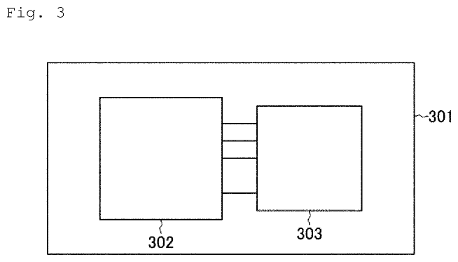

FIG. 4 is a plan view showing a configuration of the transmission line substrate.

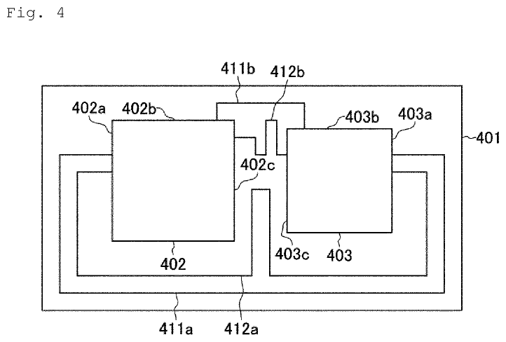

### DETAILED DESCRIPTION OF ILLUSTRATIVE EMBODIMENTS

A transmission line substrate according to an embodiment of the present invention will be described below.

### First Embodiment

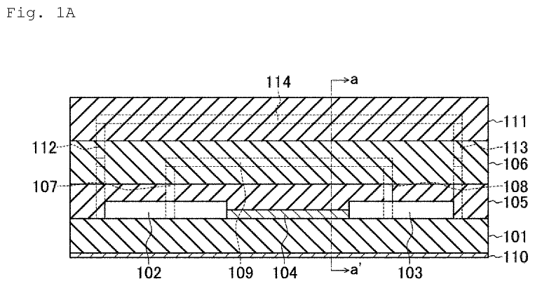

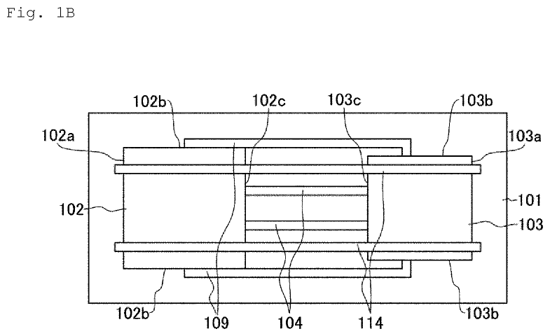

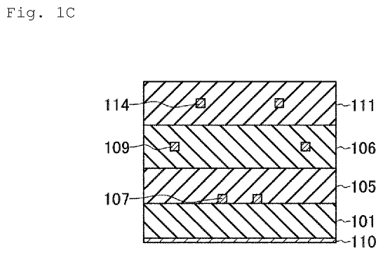

First, a transmission line substrate according to a first embodiment of the present invention will be described with reference to FIGS. 1A, 1B and 1C. Note that FIG. 1C shows a cross section of line aa′ of FIG. 1A.

The transmission line substrate includes a first integrated circuit 102 and a second integrated circuit 103 disposed (mounted) on a substrate 101 made of a dielectric material. The substrate 101 is a substrate of a semiconductor package or a semiconductor chip mounting substrate. For example, although not shown, in the semiconductor package, other circuit elements are also mounted on the substrate 101.

The transmission line substrate includes a first transmission line 104 of a first line length which is formed on the substrate 101 and connects the first integrated circuit 102 and the second integrated circuit 103. The first transmission line 104 is a strip-like transmission line made of a conductive member such as Au. In this example, two first transmission lines 104 are provided. The number of the first transmission lines 104 is not limited to two.

The transmission line substrate includes a first dielectric layer 105 which is formed to cover the first integrated circuit 102, the second integrated circuit 103, and the first transmission line 104, and is made of a dielectric having a first dielectric constant, and a second dielectric layer 106 which is formed on the first dielectric layer 105 and is made of a dielectric having a second dielectric constant.

The transmission line substrate includes a columnar first via 107 which is connected to the first integrated circuit 102 and penetrates through the first dielectric layer 105 to the middle of the second dielectric layer 106, and a columnar second via 108 which is connected to the second integrated circuit 103 and penetrates through the first dielectric layer 105 to the middle of the second dielectric layer 106. A thickness (depth) of the first via 107 and the second via 108 is, for example, about 100 μm.

Also, the transmission line substrate includes a second transmission line 109 having a second line length which is formed in the second dielectric layer 106, is connected to the first via 107 and the second via 108, and connects the first integrated circuit 102 and the second integrated circuit 103. In addition, a ground layer 110 is formed on the back side of the substrate 101.

Here, when the first line length is longer than the second line length, the second dielectric constant is lower than the first dielectric constant, and when the second line length is longer than the first line length, the first dielectric constant is lower than the second dielectric constant. The first dielectric constant and the second dielectric constant are set in a state in which transmission times of signals in the first transmission line 104 and the second transmission line 109 are equal.

In this example, a third dielectric layer 111 formed on the second dielectric layer 106 and made of a dielectric having a third dielectric constant, a columnar third via 112 which is connected to the first integrated circuit 102, penetrates through the first dielectric layer 105 and the second dielectric layer 106 and penetrates to the middle of the third dielectric layer 111, and a columnar fourth via 113 which is connected to the second integrated circuit 103, penetrates through the first dielectric layer 105 and the second dielectric layer 106, and penetrates to the middle of the third dielectric layer 111 are included. The thickness (depth) of the third via 112 and the fourth via 113 is, for example, up to about 100 μm.

A third transmission line 114 of a third line length formed in the third dielectric layer 111 is connected to the first via 107 and the second via 108. The third transmission line 114 connects the first integrated circuit 102 and the second integrated circuit 103. When the second line length is longer than the third line length, the third dielectric constant is lower than the second dielectric constant, and when the third line length is longer than the second line length, the second dielectric constant is lower than the third dielectric constant. Further, the second dielectric constant and the third dielectric constant are set in a state in which the transmission times of the signals in the second transmission line 109 and the third transmission line 114 are equal.

In this example, for the line lengths, the first transmission line 104<the second transmission line 109<the third transmission line 114. For the dielectric constants, the first dielectric constant>the second dielectric constant>the third dielectric constant. In this example, the first transmission line 104, the second transmission line 109, and the third transmission line 114 are connected to each other linearly in a plan view. The first transmission line 104, the second transmission line 109, and the third transmission line 114 need not be formed linearly in a plan view.

The first integrated circuit 102 and the second integrated circuit 103 are provided with input/output portions on respective sides 102a to 102d and 103a to 103d, and the opposite input/output terminals are connected by corresponding transmission lines. The first integrated circuit 102 and the second integrated circuit 103 are connected by two third transmission lines 114 in which the linear distance between the input/output portions of the outside sides 102a and 103a is maximum and the line length is maximum. In the first integrated circuit 102 and the second integrated circuit 103, the linear distance between the input/output portions of the sides 102b and 102c and the sides 103b and 103c is slightly short, and they are connected by respective second transmission lines 109.

The first integrated circuit 102 and the second integrated circuit 103 are connected by a first transmission line 104 in which a linear distance between input/output portions of sides 102d and 103d is minimum and a line length is minimum. In the first integrated circuit 102, a large number of input/output terminals can be formed on each of the sides 102a to 102d, and in the second integrated circuit 103, a large number of input/output terminals can be formed on each of the sides 103a to 103d. A transmission line is provided for each input/output terminal.

Each of the substrate 101, the first dielectric layer 105, the second dielectric layer 106, and the third dielectric layer 111 is made of a dielectric insulating material which has a low dielectric constant and is excellent in low Tan δ (dielectric loss tangent) characteristics, that is, high frequency characteristics, and has a predetermined thickness. These can be made up of, for example, an organic base material made of a resin material such as benzocyclobutene (BCB), polyphenylene ether resin (PPE), bismalidotriazine (BT-resin), polyimide resin, epoxy resin, cyanate resin and phenol resin, as specific examples. The substrate 101 may be made up of, for example, an inorganic base material such as ceramic or a mixture of the inorganic base material and an organic base material such as glass epoxy.

The substrate 101, the first dielectric layer 105, the second dielectric layer 106, and the third dielectric layer 111 can be formed by a multilayer structure in which a wiring pattern, a ground pattern, and the like are formed in an inner layer, and each of these may be formed of a double-sided substrate. The first transmission line 104, the second transmission line 109, the third transmission line 114, the first via 107, the second via 108, the third via 112 and the fourth via 113 can be formed by a pattern forming method using a known deposition technique, a photolithography technique, an etching technique, or the like.

The first transmission line 104 is formed in a region of the first dielectric layer 105 having a first dielectric constant 82, the second transmission line 109 is formed in a region of the second dielectric layer 106 having a second dielectric constant ε3, and the third transmission line 114 is formed in a region of the third dielectric layer 111 having a third dielectric constant ε4. Here, as described above, the first dielectric constant ε2>the second dielectric constant ε3>the third dielectric constant ε4 is satisfied.

Here, the phase velocity vp of the sine wave propagating through the transmission line can be expressed by “vp=2πf/kz . . . (1). Here, kz represents a phase constant (imaginary term of propagation constant), and f represents a frequency.

When a phase velocity propagating in a vacuum is defined as vp0, a phase constant is defined as kz0, and a wavelength is defined as λ0 for a sine wave, “vp0=2πf/kz0=fλ0 . . . (2)” is obtained from Equation (1).

When the transmission line is formed of a microstrip line on a dielectric substrate having a dielectric constant εr, the phase constant kz is “kz=√εw×kz0 . . . (3)”.

Here, εw is an effective dielectric constant, and is expressed by “εw=1+q(εr−1) . . . (4)” when using a filling factor q (a ratio in which the periphery of the transmission line is covered with a dielectric material) determined by an electric field distribution between a dielectric substrate on which the microstrip line is formed and air. Since all the electric field of the strip line is present in the dielectric and q=1, εw=εr is obtained from Equation (4).

The phase velocity vp of the transmission line formed of a microstrip line on a dielectric substrate having a dielectric constant εr is “vp=2πf/kz=fλ, vp=2πf/(√εw×kz0)=fλ, vp=vp0/√εw=fλ0/√εw . . . (5)” from Equations (1) to (4).

Therefore, the transmission line formed on the substrate or layer made of a dielectric material has such a characteristic that the propagation speed of the signal gradually decreases as the dielectric constant increases, as is apparent from Equation (5). In the transmission line substrate, a signal transmitted between the first integrated circuit 102 and the second integrated circuit 103 via each transmission line can be regarded as a digital modulation signal or an electric signal made of an aggregate of various high-frequency sine waves.

In the transmission line substrate, as described above, the third transmission line 114 having the maximum line length is formed on the third dielectric layer 111 having the low dielectric constant ε4, the second transmission line 109 is formed on the second dielectric layer 106 having the medium dielectric constant ε3, and the first transmission line 104 having the minimum line length is formed on the first dielectric layer 105 having the high dielectric constant ε2. The first dielectric constant, the second dielectric constant, and the third dielectric constant are set in a state in which transmission time of signals in each of the first transmission line 104, the second transmission line 109, and the third transmission line 114 are equal.

In the transmission line substrate according to the embodiment, each transmission line which connects the first integrated circuit 102 and the second integrated circuit 103 have different line lengths depending on the configuration, but the transmission rates of the high-frequency signals to be transmitted are adjusted by forming the transmission lines on the dielectric layers having different dielectric constants, and a transmission line having an equal length can be constituted in a pseudo manner.

As described above, according to the first embodiment, the transmission line can be freely formed in the dielectric layer without redundant wiring, and the signal transmission characteristics can be improved. Further, since the regions having different dielectric constants are formed in a stacking direction, the semiconductor device can be manufactured by a manufacturing technique for integrating (stacking) in a vertical direction. As a result, improvements in the accuracy and yield of the process can be expected as compared with a case where regions having different dielectric constants are manufactured by photolithography and etching in a horizontal direction, and the degree of freedom of design is improved because an occupied area is not affected. Further, even if the number of input terminals of the integrated circuit to be connected increases, since there is a configuration in which the transmission lines are disposed in the vertical direction, the high density and the miniaturization can be attained. Thus, low power consumption, miniaturization and cost reduction can be realized.

In the above description, embodiments of the present invention are described with respect to a transmission line between the first integrated circuit 102 and the second integrated circuit 103, although six transmission lines and four dielectric layers including the substrate 101 have been described as an example, it is needless to say that the present invention is not limited thereto. The transmission line is not limited to a strip-like transmission line, but may be a coplanar line.

### Second Embodiment

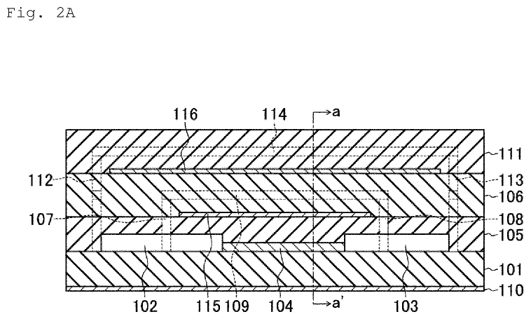

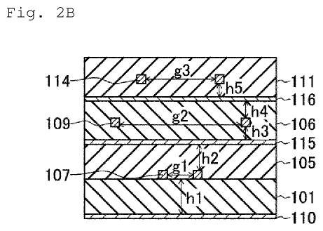

A transmission line substrate according to a second embodiment of the present invention will be described with reference to FIGS. 2A and 2B. FIG. 2B shows a cross section of line aa′ of FIG. 2A.

The transmission line substrate includes a first integrated circuit 102 and a second integrated circuit 103 disposed (mounted) on a substrate 101 made of a dielectric material. The transmission line substrate includes a first transmission line 104 of a first line length which is formed on the substrate 101 and connects the first integrated circuit 102 and the second integrated circuit 103.

The transmission line substrate includes a first dielectric layer 105 which is formed to cover the first integrated circuit 102, the second integrated circuit 103, and the first transmission line 104, and is made of a dielectric having a first dielectric constant, and a second dielectric layer 106 which is formed on the first dielectric layer 105 and is made of a dielectric having a second dielectric constant.

The transmission line substrate includes a first via 107 which is connected to the first integrated circuit 102 and penetrates through the first dielectric layer 105 to the middle of the second dielectric layer 106, and a second via 108 which is connected to the second integrated circuit 103, and penetrates through the first dielectric layer 105 to the middle of the second dielectric layer 106.

The transmission line substrate includes a second transmission line 109 having a second line length which is formed in the second dielectric layer 106, connected to the first via 107 and the second via 108, and connects the first integrated circuit 102 and the second integrated circuit 103. In addition, a ground layer 110 is formed on the back side of the substrate 101.

In this example, a third dielectric layer 111 which is formed on the second dielectric layer 106 and made of a dielectric having a third dielectric constant, a third via 112 which is connected to the first integrated circuit 102 and penetrates through the first dielectric layer 105 and the second dielectric layer 106 to the middle of the third dielectric layer 111, and a fourth via 113 which is connected to the second integrated circuit 103, and penetrates through the first dielectric layer 105 and the second dielectric layer 106 to the middle of the third dielectric layer 111 are provided.

A third transmission line 114 of a third line length formed in the third dielectric layer 111 is connected to the first via 107 and the second via 108. The third transmission line 114 connects the first integrated circuit 102 and the second integrated circuit 103.

The aforementioned configurations are similar to those described in the first embodiment. In the second embodiment, a first ground plane 115 formed between the first dielectric layer 105 and the second dielectric layer 106 is included. Further, a second ground plane 116 formed between the second dielectric layer 106 and the third dielectric layer 111 is included. Each ground plane is formed in a region not connected to each via. The first ground plane 115 is disposed just below the second transmission line 109, and the second ground plane 116 is disposed just below the third transmission line 114.

In the second embodiment, a distance (h2) between the first via 107 and the first ground plane 115 is smaller than a distance (g1) between the two first vias 107 (h2<g1, g1<h1). Therefore, an electric field generated between the first via 107 and the first ground plane 115 becomes large. As a result, an electric field generated from one of the two first vias 107 is deflected in a direction in which the first ground plane 115 exists by the first via 107 and the first ground plane 115, an electric field transmitted in the other direction of the two first vias 107 is suppressed, and crosstalk noise can be reduced.

The same also applies to the case of the two second transmission lines 109 and the two third transmission lines 114. A distance h3 between the second transmission line 109 and the first ground plane 115, and a distance h4 between the second transmission line 109 and the second ground plane 116 are smaller than a distance (g2) between the two second transmission lines 109. A distance h5 between the third transmission line 114 and the second ground plane 116 is smaller than a distance (g3) between the two third transmission lines 114. Thus, crosstalk noise between the transmission lines can be reduced. Further, crosstalk noise between the transmission lines adjacent to each other in the stacking direction of each dielectric layer becomes substantially zero due to the presence of the ground plane.

As described above, according to the second embodiment, it is possible to achieve both high density and reduction of crosstalk noise. Further, by adjusting the distance between the transmission line and the ground plane by the ground plane and the transmission line existing just below or just above the transmission line or both, the degree of freedom is higher than that of the normal strip line or microstrip line, and the characteristic impedance of the transmission line can be set.

As described above, according to embodiments of the present invention, when the first line length is longer than the second line length, by making the second dielectric constant lower than the first dielectric constant, and when the second line length is longer than the first line length, by making the first dielectric constant lower than the second dielectric constant, the transmission rate of the high frequency signal to be transmitted is adjusted, and the transmission lines of the same length are constituted in a pseudo manner. Accordingly, the high frequency signal can be transmitted without making the wiring structure redundant, and without increasing the loss between the transmission lines of different line lengths. According to embodiments of the present invention, it is possible to provide a transmission line substrate which improves signal transmission characteristics and achieves low power consumption, miniaturization, and cost reduction.

According to embodiments of the present invention, the first transmission line and the second transmission line are disposed vertically when viewed from the substrate, and the first dielectric constant and the second dielectric constant of the first dielectric layer and the second dielectric layer in which each transmission line is formed are set in a state in which the signal transmission times in each of the first transmission line and the second transmission line are equal. Accordingly, each transmission line can be freely formed without redundant wiring, and signal transmission characteristics can be improved. Since each transmission line is integrated in the vertical direction, an integrated manufacturing technique can be applied, and the accuracy and yield of the process can be improved, and the degree of freedom of design can be improved. Further, even if the number of input terminals of the integrated circuit is increased, since they are constituted in the vertical direction, the high density and miniaturization can be attained.

Furthermore, crosstalk noise between transmission lines can be reduced, and the characteristic impedance of the line can be set with a higher degree of freedom than that of an ordinary strip line or a microstrip line. Thus, the improvement of wiring density and the reduction of crosstalk noise between wirings are made compatible, and the reduction of power consumption, miniaturization and cost reduction can be realized.

Note that it is clear that the present invention is not limited to the embodiments described above and within the technical concept of the present invention and many modifications and combinations can be implemented by those skilled in the art.

### REFERENCE SIGNS LIST

101 Substrate
102 First integrated circuit
103 Second integrated circuit
104 First transmission line
105 First dielectric layer
106 Second dielectric layer
107 First via
108 Second via
109 Second transmission line
110 Ground layer
111 Third dielectric layer
112 Third via
113 Fourth transmission line
114 Third transmission line

1-4. (canceled)

5. A transmission line substrate comprising:
a first integrated circuit and a second integrated circuit disposed on a front face of a substrate made of a dielectric;
a first transmission line of a first line length on the substrate, the first transmission line connecting the first integrated circuit to the second integrated circuit;
a first dielectric layer covering the first integrated circuit, the second integrated circuit, and the first transmission line, and the first dielectric layer having a first dielectric constant;
a second dielectric layer on the first dielectric layer, the second dielectric layer having a second dielectric constant;
a columnar first via connected to the first integrated circuit, the columnar first via penetrating through the first dielectric layer into the second dielectric layer;
a columnar second via connected to the second integrated circuit, the columnar second via penetrating through the first dielectric layer into the second dielectric layer;
a second transmission line of a second line length in the second dielectric layer, the second transmission line is connected to the columnar first via and the columnar second via to connect the first integrated circuit and the second integrated circuit; and
a ground layer on a back face of the substrate, wherein the first line length is longer than the second line length, and the second dielectric constant is lower than the first dielectric constant, or wherein the second line length is longer than the first line length, and the first dielectric constant is lower than the second dielectric constant.

6. The transmission line substrate according to claim 5, further comprising:
a first ground plane between the first dielectric layer and the second dielectric layer.

7. The transmission line substrate according to claim 5, wherein the first dielectric constant and the second dielectric constant are set in a state in which transmission times of signals in the first transmission line and the second transmission line are equal.

8. The transmission line substrate according to claim 5,
wherein the first transmission line and the second transmission line are disposed linearly in a plan view.

9. The transmission line substrate according to claim 5, wherein the first line length is longer than the second line length, and the second dielectric constant is lower than the first dielectric constant.

10. The transmission line substrate according to claim 5, wherein the second line length is longer than the first line length, and the first dielectric constant is lower than the second dielectric constant.

11. A transmission line substrate comprising:
a first integrated circuit and a second integrated circuit disposed on a first side of a substrate made of a dielectric;
a first transmission line of a first line length on the substrate, the first transmission line connecting the first integrated circuit to the second integrated circuit;
a first dielectric layer covering the first integrated circuit, the second integrated circuit, and the first transmission line, and the first dielectric layer having a first dielectric constant;
a second dielectric layer on the first dielectric layer, the second dielectric layer having a second dielectric constant;
a first via connected to the first integrated circuit, the first via being at least partially disposed in the first dielectric layer and the second dielectric layer;
a second via connected to the second integrated circuit, the second via being at least partially disposed in the first dielectric layer and the second dielectric layer;
a second transmission line of a second line length in the second dielectric layer, the second transmission line is connected to the first integrated circuit and the second integrated circuit by the first via and the second via, respectively; and
a ground layer on a second side of the substrate, wherein the first line length is longer than the second line length, and the second dielectric constant is lower than the first dielectric constant.

12. The transmission line substrate according to claim 11, further comprising:
a first ground plane between the first dielectric layer and the second dielectric layer.

13. The transmission line substrate according to claim 11, wherein transmission times of signals in the first transmission line and the second transmission line are equal.

14. The transmission line substrate according to claim 11,
wherein the first transmission line and the second transmission line are linear in a plan view.

15. A transmission line substrate comprising:
a first integrated circuit and a second integrated circuit disposed on a first side of a substrate made of a dielectric;
a first transmission line of a first line length on the substrate, the first transmission line connecting the first integrated circuit to the second integrated circuit;
a first dielectric layer covering the first integrated circuit, the second integrated circuit, and the first transmission line, and the first dielectric layer having a first dielectric constant;
a second dielectric layer on the first dielectric layer, the second dielectric layer having a second dielectric constant;
a first via connected to the first integrated circuit, the first via being at least partially disposed in the first dielectric layer and the second dielectric layer;
a second via connected to the second integrated circuit, the second via being at least partially disposed in the first dielectric layer and the second dielectric layer;
a second transmission line of a second line length in the second dielectric layer, the second transmission line is connected to the first integrated circuit and the second integrated circuit by the first via and the second via, respectively; and
a ground layer on a second side of the substrate, wherein the second line length is longer than the first line length, and the first dielectric constant is lower than the second dielectric constant.

16. The transmission line substrate according to claim 15, further comprising:
a first ground plane between the first dielectric layer and the second dielectric layer.

17. The transmission line substrate according to claim 15, wherein transmission times of signals in the first transmission line and the second transmission line are equal.

18. The transmission line substrate according to claim 15,
wherein the first transmission line and the second transmission line are linear in a plan view.
